(19) United States
(12) Patent Application Publication
(10) Pub. No.: US 2025/0233578 A1
(43) Pub. Date: Jul. 17, 2025

(54) FILTER CIRCUIT

(71) Applicant: TDK Corporation, Tokyo (JP)

(72) Inventor: Kazuhiro TSUKAMOTO, Tokyo (JP)

(73) Assignee: TDK Corporation, Tokyo (JP)

(21) Appl. No.: 19/013,534

(22) Filed: Jan. 8, 2025

(30) Foreign Application Priority Data
Jan. 15, 2024 (JP) 2024-003787

(51) Int. Cl. H03H 9/54; H03H 7/01

(52) U.S. Cl. CPC H03H 9/542; H03H 7/0161; H03H 7/1783

(57) ABSTRACT

A filter circuit includes an inductor provided between a signal path and a ground and including a first end electrically connected to the ground, a resonator provided between the signal path and the ground and including a third end electrically connected to the ground, and a capacitor provided on the signal path and electrically connected to a second end of the inductor and a fourth end of the resonator. The inductor is configured using an inductor element. The resonator is configured without using the inductor element.

### CROSS-REFERENCE TO RELATED APPLICATION

This application claims the benefit of Japanese Priority Patent Application No. 2024-003787 filed on Jan. 15, 2024, the entire contents of which are incorporated herein by reference.

### BACKGROUND

The disclosure relates to a filter circuit including a resonator.

Various filters such as a low-pass filter, a high-pass filter, and a band-pass filter are configured using a plurality of resonators. As resonators used in these filters, for example, an LC resonator configured using an inductor and a capacitor, a stripline resonator configured using a conductor line (distributed constant line), and an acoustic wave resonator configured using an acoustic wave element are known. The acoustic wave element is an element using an acoustic wave. Examples of the acoustic wave element include a surface acoustic wave element using a surface acoustic wave and a bulk acoustic wave element using a bulk acoustic wave.

JP 2004-23334 A1 discloses a band-pass filter including a plurality of stripline resonators, a first notch circuit which is a series circuit including an inductor and a capacitor arranged between a signal input terminal and a ground, and a second notch circuit which is a series circuit including an inductor and a capacitor arranged between a signal output terminal and the ground. The first and second notch circuits have a function that increases out-of-band attenuation of the band-pass filter.

In general, filters configured using an acoustic wave resonator are suitable for achieving pass attenuation characteristics that steeply change in a frequency domain close to the cutoff frequency, but have a problem that they are not suitable for achieving a wide passband. The above problem is not limited to filters configured using the acoustic wave resonator, but applies to filters in general configured using resonators having steep resonance characteristics.

Meanwhile, in recent years, the market has been demanding downsizing and more space-saving of compact mobile communication apparatuses, and there is also a demand for downsizing of filters to be used in the communication apparatuses. In order to downsize filters, it is desirable to be able to achieve desired characteristics with a simple structure.

### SUMMARY

A filter circuit according to one embodiment of the disclosure includes an input port, an output port, a signal path connecting the input port and the output port, a first inductor provided between the signal path and a ground, and including a first end electrically connected to the ground and a second end opposite to the first end, a resonator provided between the signal path and the ground, and including a third end electrically connected to the ground and a fourth end opposite to the third end, and a first capacitor provided on the signal path, and electrically connected to the second end of the first inductor and the fourth end of the resonator. The first inductor is configured using an inductor element. The resonator is configured without using the inductor element.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a circuit diagram showing a circuit configuration of a filter circuit according to an example embodiment of the disclosure.

FIG. 2 is a perspective view showing a main body of the filter circuit according to the example embodiment of the disclosure.

FIG. 3 is a perspective view showing an element portion of the main body in the example embodiment of the disclosure.

FIG. 4 is a perspective view showing the element portion of the main body in the example embodiment of the disclosure.

FIG. 5A to FIG. 5C are explanatory diagrams showing respective patterned surfaces of first to third dielectric layers in the element portion of the main body in the example embodiment of the disclosure.

FIG. 6A is an explanatory diagram showing a patterned surface of a fourth dielectric layer in the element portion of the main body in the example embodiment of the disclosure.

FIG. 6B is an explanatory diagram showing a patterned surface of each of fifth and sixth dielectric layers in the element portion of the main body in the example embodiment of the disclosure.

FIG. 6C is an explanatory diagram showing a patterned surface of a seventh dielectric layer in the element portion of the main body in the example embodiment of the disclosure.

FIG. 7A is an explanatory diagram showing a patterned surface of each of eighth and nineth dielectric layers in the element portion of the main body in the example embodiment of the disclosure.

FIG. 7B and FIG. 7C are explanatory diagrams showing respective patterned surfaces of tenth and eleventh dielectric layers in the element portion of the main body in the example embodiment of the disclosure.

FIG. 8A to FIG. 8C are explanatory diagrams showing respective patterned surfaces of twelfth to fourteenth dielectric layers in the element portion of the main body in the example embodiment of the disclosure.

FIG. 9A to FIG. 9C are explanatory diagrams showing respective patterned surfaces of fifteenth to seventeenth dielectric layers in the element portion of the main body in the example embodiment of the disclosure.

FIG. 10A and FIG. 10B are explanatory diagrams showing respective patterned surfaces of eighteenth and nineteenth dielectric layers in the element portion of the main body in the example embodiment of the disclosure.

FIG. 10C is an explanatory diagram showing an electrode formation surface of the nineteenth dielectric layer.

FIG. 11 is a perspective view showing an inside of the element portion of the main body in the example embodiment of the disclosure.

FIG. 12 is a plan view showing the inside of the element portion of the main body in the example embodiment of the disclosure.

FIG. 13 is a circuit diagram showing a first circuit used in a simulation.

FIG. 14 is a characteristic diagram showing characteristics of the first circuit obtained by the simulation.

FIG. 15 is a circuit diagram showing a second circuit used in a simulation.

FIG. 16 is a characteristic diagram showing characteristics of the second circuit obtained by the simulation.

FIG. 17 is a circuit diagram showing a third circuit used in a simulation.

FIG. 18 is a characteristic diagram showing characteristics of the third circuit obtained by the simulation.

FIG. 19 is a circuit diagram showing a fourth circuit used in a simulation.

FIG. 20 is a characteristic diagram showing characteristics of the fourth circuit obtained by the simulation.

FIG. 21 is a circuit diagram showing a fifth circuit used in a simulation.

FIG. 22 is a characteristic diagram showing characteristics of the fifth circuit obtained by the simulation.

FIG. 23 is a characteristic diagram showing an example of pass attenuation characteristics of the main body according to the example embodiment of the disclosure.

### DETAILED DESCRIPTION

An object of the disclosure is to provide a filter circuit capable of achieving a wide passband with a simple structure.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Initially, a schematic configuration of a filter circuit 1 according to an example embodiment of the disclosure will be described. The filter circuit 1 according to the example embodiment is a band-pass filter configured to selectively pass a signal of a frequency within a predetermined passband.

The filter circuit 1 according to the example embodiment includes at least one resonator configured without using an inductor element. The at least one resonator can be configured using an acoustic wave element, for example. The acoustic wave element may be, for example, a bulk acoustic wave element, or a surface acoustic wave element.

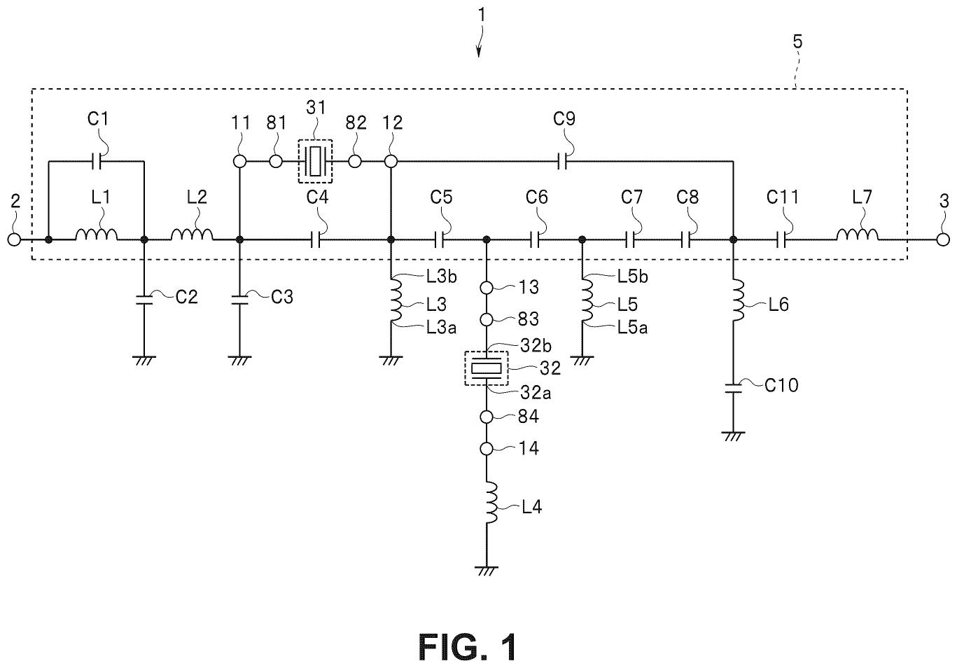

Next, an example of a circuit configuration of the filter circuit 1 will be described with reference to FIG. 1. FIG. 1 is a circuit diagram showing the circuit configuration of the filter circuit 1. The filter circuit 1 includes an input port 2 to which a signal is input, an output port 3 from which a signal is output, and a signal path 5 connecting the input port 2 and the output port 3.

The filter circuit 1 further includes inductors L1, L2, L3, L5, L6, and L7, and capacitors C1, C2, C3, C4, C5, C6, C7, C8, C9, C10, and C11. The inductors L1 to L3 and L5 to L7 and the capacitors C1 to C11 are provided between the input port 2 and the output port 3 in a circuit configuration. Note that in the present application, the expression “in the (a) circuit configuration” is used to indicate not layout in a physical configuration but layout in the circuit diagram.

The inductors L1, L2, and L7 and the capacitors C1, C4 to C9, and C11 are provided on the signal path 5. One end of the inductor L1 is connected to the input port 2. One end of the inductor L2 is connected to another end of the inductor L1.

One end of the capacitor C4 is connected to another end of the inductor L2. One end of the capacitor C5 is connected to another end of the capacitor C4. One end of the capacitor C6 is connected to another end of the capacitor C5. One end of the capacitor C7 is connected to another end of the capacitor C6. One end of the capacitor C8 is connected to another end of the capacitor C7.

One end of the capacitor C11 is connected to another end of the capacitor C8. One end of the inductor L7 is connected to another end of the capacitor C11. Another end of the inductor L7 is connected to the output port 3.

The capacitor C1 is connected in parallel with the inductor L1. One end of the capacitor C9 is connected to one end of the capacitor C5. Another end of the capacitor C9 is connected to the other end of the capacitor C8.

The inductors L3, L5, and L6 and the capacitors C2, C3, and C10 are provided between the signal path 5 and the ground. One end of the capacitor C2 is connected to a connection point of the inductors L1 and L2. One end of the capacitor C3 is connected to a connection point of the inductor L2 and the capacitor C4. Another end of each of the capacitors C2 and C3 is connected to the ground.

The inductor L3 includes a first end L3a electrically connected to the ground, and a second end L3b opposite to the first end L3a. The inductor L5 includes a first end L5a electrically connected to the ground, and a second end L5b opposite to the first end L5a. The second end L3b of the inductor L3 is connected to a connection point of the capacitors C4, C5, and C9 on the signal path 5. The second end L5b of the inductor L5 is connected to a connection point of the capacitors C6 and C7 on the signal path 5. Note that in the present application, the expression “electrically connected” includes a case of being electrically connected via a metallic conductor (including an inductor), but does not include a case of being connected via a capacitor.

One end of the inductor L6 is connected to a connection point of the capacitors C8, C9, and C11. One end of the capacitor C10 is connected to another end of the inductor L6. Another end of the capacitor C10 is connected to the ground.

The filter circuit 1 further includes a resonator 31 provided on the signal path 5, a resonator 32 provided between the signal path 5 and the ground, and signal ports 81, 82, 83, and 84. The resonator 31 is provided between the signal port 81 and the signal port 82 in the circuit configuration. The resonator 32 is provided between the signal port 83 and the signal port 84 in the circuit configuration. Each of the resonators 31 and 32 is configured without using an inductor element. In the example embodiment in particular, each of the resonators 31 and 32 is an acoustic wave resonator configured using at least one acoustic wave element.

The filter circuit 1 further includes signal ports 11, 12, 13, and 14 connected to the signal ports 81, 82, 83, and 84, respectively. Note that, in FIG. 1, the signal port 12 is drawn as being located between the one end of the capacitor C9 and the one end of the capacitor C5, for convenience. However, the signal port 12 may not be located between the one end of the capacitor C9 and the one end of the capacitor C5.

The capacitor C4 is connected in parallel with the resonator 31. The other end of the inductor L2 and one end of each of the capacitors C3 and C4 are connected to one end of the resonator 31 through the signal ports 11 and 81 in order. The second end L3b of the inductor L3, the other end of the capacitor C4, and the one end of the capacitor C5 are connected to another end of the resonator 31 through the signal ports 12 and 82 in order.

The resonator 32 includes a first end 32a electrically connected to the ground, and a second end 32b opposite to the first end 32a. The other end of the capacitor C5 and one end of the capacitor C6 are connected to the second end 32b of the resonator 32 through the signal ports 13 and 83 in order. The filter circuit 1 further includes an inductor L4. One end of the inductor L4 is connected to the first end 32a of the resonator 32 through the signal ports 14 and 84 in order. Another end of the inductor L4 is connected to the ground.

The first end 32a of the resonator 32 is electrically connected to the ground via the inductor L4. The capacitor C5 is provided on the signal path 5, and is electrically connected to the second end L3b of the inductor L3 and the second end 32b of the resonator 32. The capacitor C6 is provided on the signal path 5, and is electrically connected to the second end L5b of the inductor L5 and the second end 32b of the resonator 32.

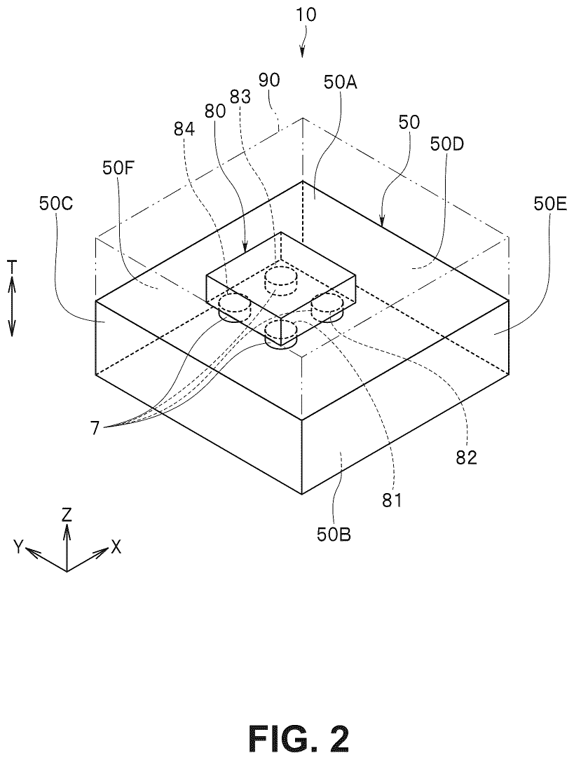

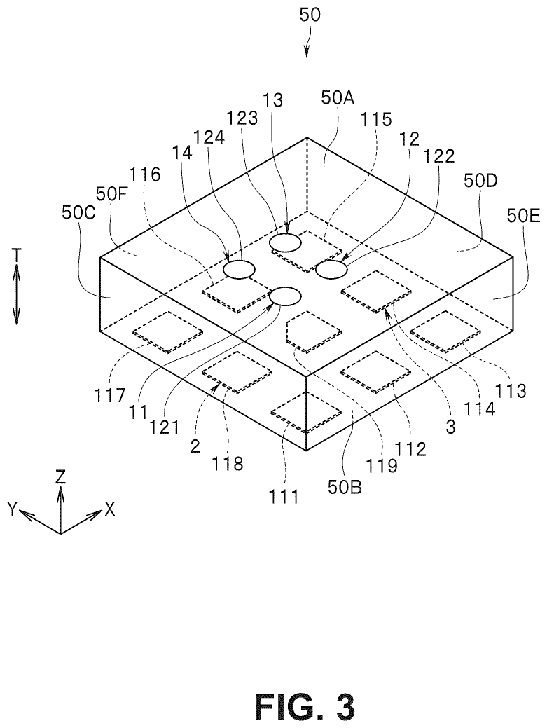

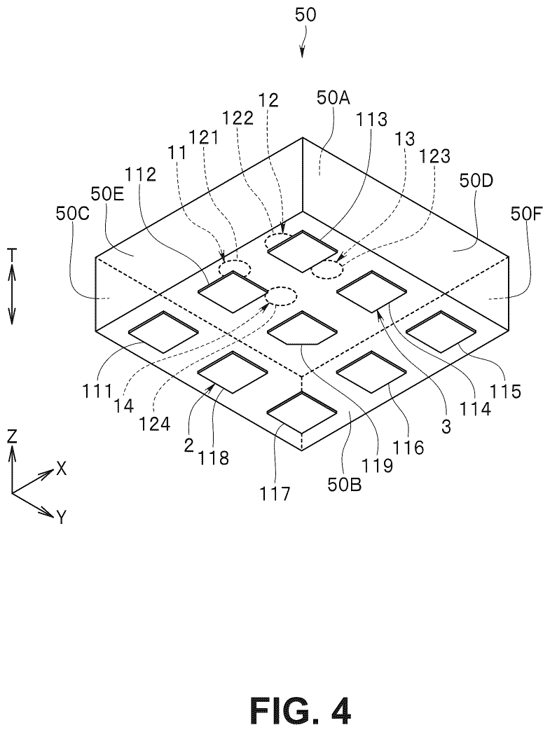

The filter circuit 1 includes a main body 10 for integrating the input port 2, the output port 3, the signal path 5, the signal ports 11 to 14 and 81 to 84, the resonators 31 and 32, the inductors L1 to L7, and the capacitors C1 to C11. Hereinafter, a configuration of the main body 10 will be described with reference to FIG. 2 to FIG. 4. FIG. 2 is a perspective view showing the main body 10. FIG. 3 and FIG. 4 are perspective views showing an element portion of the main body 10.

The main body 10 includes an element portion 50. The element portion 50 is a stack including a plurality of dielectric layers stacked together, and a plurality of conductors (a plurality of conductor layers and a plurality of through holes). The inductors L1 to L7 and the capacitors C1 to C11 shown in FIG. 1 are configured by the plurality of dielectric layers and the plurality of conductors. Each of the plurality of dielectric layers is formed of a dielectric material. In the example embodiment, low temperature co-fired ceramics (LTCC) is used as a dielectric material.

The element portion 50 includes a first surface 50A and a second surface 50B located at both ends of the plurality of dielectric layers in a stacking direction T, and four side surfaces 50C to 50F connecting the first surface 50A and the second surface 50B. The side surfaces 50C and 50D face opposite sides of each other, and the side surfaces 50E and 50F also face opposite sides of each other. The side surfaces 50C to 50F each are perpendicular to the first surface 50A and the second surface 50B.

Here, an X direction, a Y direction, and a Z directions will be defined as shown in FIG. 2 to FIG. 4. The X, Y, and the Z directions are orthogonal to one another. In the example embodiment, one direction parallel to the stacking direction T is defined as the Z direction. The Z direction is also one direction parallel to a direction in which the element portion 50 and a mounted component 80 are arranged. The opposite directions to the X, Y, and Z directions are defined as −X, −Y, and −Z directions, respectively. The expression “when seen in a predetermined direction (the Z direction, for example)” means that an object is seen from a position away in the predetermined direction or one direction parallel to the predetermined direction.

As shown in FIG. 3 and FIG. 4, the first surface 50A is located at an end of the element portion 50 in the Z direction. The first surface 50A is also a top surface of the element portion 50, and is also a mounting surface for mounting a mounted component described later. The second surface 50B is located at an end of the element portion 50 in the −Z direction. The second surface 50B is also a bottom surface of the element portion 50. FIG. 3 shows the element portion 50 seen from the first surface 50A side. FIG. 4 shows the element portion 50 seen from the second surface 50B side.

The side surface 50C is located at an end of the element portion 50 in the −X direction. The side surface 50D is located at an end of the element portion 50 in the X direction. The side surface 50E is located at an end of the element portion 50 in the −Y direction. The side surface 50F is located at an end of the element portion 50 in the Y direction.

The element portion 50 further includes a plurality of electrodes 111, 112, 113, 114, 115, 116, 117, 118, and 119 provided on the second surface 50B of the element portion 50. The electrodes 111, 112, and 113 are arranged in this order in the X direction at positions closer to the side surface 50E than to the side surface 50F. The electrodes 115, 116, and 117 are arranged in this order in the −X direction at positions closer to the side surface 50F than to the side surface 50E.

The electrode 114 is located between the electrode 113 and the electrode 115. The electrode 118 is located between the electrode 111 and the electrode 117. The electrode 119 is located between the electrode 112 and the electrode 116. In addition, the electrode 119 is located substantially at a center of the second surface 50B.

The electrode 118 corresponds to the input port 2. The electrode 114 corresponds to the output port 3. Accordingly, the input port 2 and the output port 3 are provided on the second surface 50B of the element portion 50. Each of the electrodes 111, 112, 113, 115, 116, 117, and 119 is connected to the ground.

The element portion 50 further includes a plurality of electrodes 121, 122, 123, and 124 provided on the first surface 50A of the element portion 50. The electrodes 121 and 122 are arranged in this order in the X direction at positions closer to the side surface 50E than to the side surface 50F. The electrodes 123 and 124 are arranged in this order in the −X direction at positions closer to the side surface 50F than to the side surface 50E.

The electrode 121 corresponds to the signal port 11. The electrode 122 corresponds to the signal port 12. The electrode 123 corresponds to the signal port 13. The electrode 124 corresponds to the signal port 14. Accordingly, the signal ports 11 to 14 are provided on the first surface 50A of the element portion 50.

The main body 10 further includes the mounted component 80 that is mounted on the first surface 50A of the element portion 50. The mounted component 80 includes the resonators 31 and 32 of the filter circuit shown in FIG. 1.

The mounted component 80 further includes four electrodes corresponding to the signal ports 81, 82, 83, and 84, respectively. Note that, in FIG. 2, the four electrodes are denoted by the reference signs 81 to 84, for convenience. In a state where the mounted component 80 is mounted on the element portion 50, the four electrodes denoted by the reference signs 81 to 84 face the electrodes 121 to 124 of the element portion 50, respectively. The four electrodes denoted by the reference signs 81 to 84 are physically connected to the electrodes 121 to 124 respectively by, for example, a solder bump 7.

The main body 10 further includes a sealing portion 90 for sealing the mounted component 80. The sealing portion 90 covers a circumference of the mounted component 80 and at least a part of the first surface 50A of the element portion 50. The sealing portion 90 may further cover the side surfaces 50C to 50F of the element portion 50. The sealing portion 90 is formed of a resin, for example.

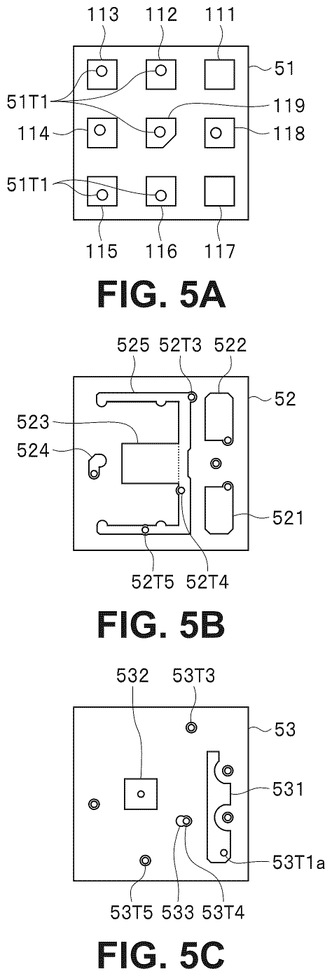

Next, an example of the plurality of dielectric layers, the plurality of conductor layers, and the plurality of through holes that constitute the element portion 50 will be described with reference to FIG. 5A to FIG. 10C. In this example, the element portion 50 includes nineteen dielectric layers stacked together. The nineteen dielectric layers are hereinafter referred to as first to nineteenth dielectric layers in the order from bottom to top. The first to nineteenth dielectric layers are denoted by the reference signs 51 to 69, respectively.

In FIG. 5A to FIG. 10B, a plurality of circles represent a plurality of through holes. Each of the dielectric layers 51 to 69 includes a plurality of through holes formed. Each of the plurality of through holes is formed by filling a hole intended for a through hole with a conductive paste. Each of the plurality of through holes is connected to an electrode, a conductor layer, or another through hole.

In FIG. 5A to FIG. 10B, a plurality of specific through holes of the plurality of through holes are denoted by reference signs. Regarding the connection relation between each of the plurality of specific through holes and an electrode, a conductor layer, or another through hole, a connection relation in a state where the first to nineteenth dielectric layers 51 to 69 are stacked together is described.

FIG. 5A shows a patterned surface of the first dielectric layer 51. The electrodes 111 to 119 are formed on the patterned surface of the dielectric layer 51. In FIG. 5A, five through holes denoted by the reference sign 51T1 are connected to the electrodes 112, 113, 115, 116, and 119, respectively. Note that, in the following description, the through hole denoted by the reference sign 51T1 is simply referred to as a through hole 51T1. Such manner for the through hole 51T1 similarly applies to one or more through holes denoted by reference signs other than the through hole 51T1.

FIG. 5B shows a patterned surface of the second dielectric layer 52. Conductor layers 521, 522, 523, 524, and 525 are formed on the patterned surface of the dielectric layer 52. The conductor layer 525 is connected to the conductor layer 523. In FIG. 5B, the boundary between the conductor layer 523 and the conductor layer 525 is shown as a dotted line. One of the five through holes 51T1 is connected to the conductor layer 523. Other four of the five through holes 51T1 and through holes 52T3, 52T4, and 52T5 shown in FIG. 5B are connected to the conductor layer 525.

FIG. 5C shows a patterned surface of the third dielectric layer 53. Conductor layers 531, 532, and 533 are formed on the patterned surface of the dielectric layer 53. A through hole 53T1a shown in FIG. 5C is connected to the conductor layer 531. The through holes 52T3 and 52T5 are respectively connected to through holes 53T3 and 53T5 shown in FIG. 5C. The through hole 52T4 and a through hole 53T4 that is shown in FIG. 5C are connected to the conductor layer 533.

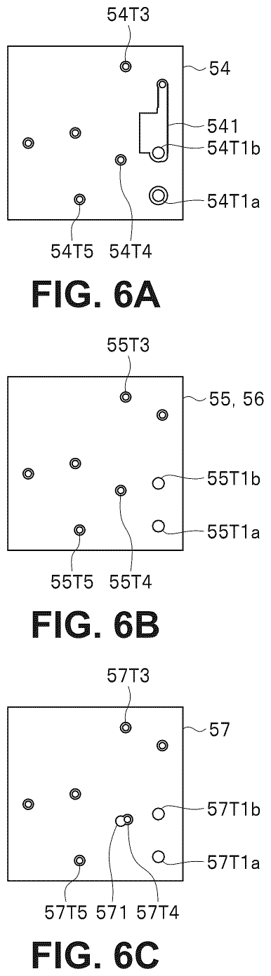

FIG. 6A shows a patterned surface of the fourth dielectric layer 54. A conductor layers 541 is formed on the patterned surface of the dielectric layer 54. A through hole 54T1b shown in FIG. 6A is connected to the conductor layer 541. The through holes 53T1a, 53T3, 53T4, and 53T5 are respectively connected to through holes 54T1a, 54T3, 54T4, and 54T5 shown in FIG. 6A.

FIG. 6B shows a patterned surface of each of the fifth and sixth dielectric layers 55 and 56. The through holes 54T1a, 54T1b, 54T3, 54T4, and 54T5 are respectively connected to through holes 55T1a, 55T1b, 55T3, 55T4, and 55T5 formed in the dielectric layer 55. In addition, in the dielectric layers 55 and 56, vertically adjacent through holes with the same reference signs are connected to each other.

FIG. 6C shows a patterned surface of the seventh dielectric layer 57. A conductor layer 571 is formed on the patterned surface of the dielectric layer 57. The through holes 55T1a, 55T1b, 55T3, and 55T5 formed in the dielectric layer 56 are respectively connected to through holes 57T1a, 57T1b, 57T3, and 57T5 shown in FIG. 6C. The through hole 55T4 formed in the dielectric layer 56 and a through hole 57T4 shown in FIG. 6C are connected to the conductor layer 571.

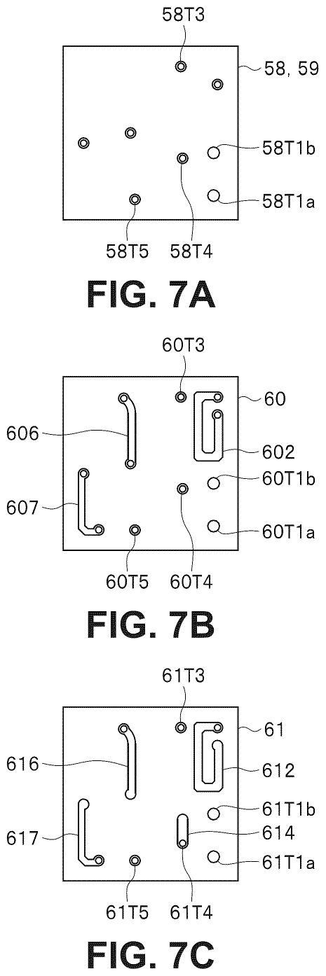

FIG. 7A shows a patterned surface of each of the eighth and nineth dielectric layers 58 and 59. The through holes 57T1a, 57T1b, 57T3, 57T4, and 57T5 are respectively connected to through holes 58T1a, 58T1b, 58T3, 58T4, and 58T5 formed in the dielectric layer 58. In addition, in the dielectric layers 58 and 59, vertically adjacent through holes with the same reference signs are connected to each other.

FIG. 7B shows a patterned surface of the tenth dielectric layer 60. Inductor conductor layers 602, 606, and 607 are formed on the patterned surface of the dielectric layer 60. The through holes 58T1a, 58T1b, 58T3, 58T4, and 58T5 formed in the dielectric layer 59 are respectively connected to through holes 60T1a, 60T1b, 60T3, 60T4, and 60T5 shown in FIG. 7B.

FIG. 7C shows a patterned surface of the eleventh dielectric layer 61. Inductor conductor layers 612, 614, 616, and 617 are formed on the patterned surface of the dielectric layer 61. The through holes 60T1a, 60T1b, 60T3, and 60T5 are respectively connected to through holes 61T1a, 61T1b, 61T3, and 61T5 shown in FIG. 7C. The through hole 60T4 and a through hole 61T4 that is shown in FIG. 7C are connected to the conductor layer 614.

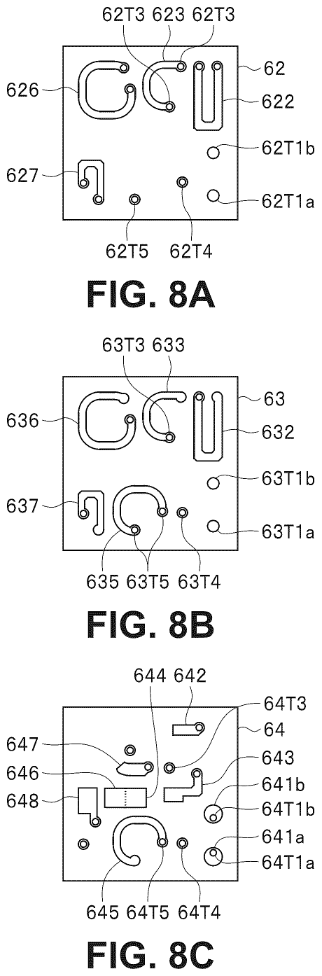

FIG. 8A shows a patterned surface of the twelfth dielectric layer 62. Inductor conductor layers 622, 623, 626, and 627 are formed on the patterned surface of the dielectric layer 62. The through holes 61T1a, 61T1b, 61T4, and 61T5 are respectively connected to through holes 62T1a, 62T1b, 62T4, and 62T5 shown in FIG. 8A. The through hole 61T3 and two through holes 62T3, shown in FIG. 8A, are connected to the conductor layer 623.

FIG. 8B shows a patterned surface of the thirteenth dielectric layer 63. Inductor conductor layers 632, 633, 635, 636, and 637 are formed on the patterned surface of the dielectric layer 63. The through holes 62T1a, 62T1b, and 62T4 are respectively connected to through holes 63T1a, 63T1b, and 63T4 shown in FIG. 8B. The two through holes 62T3 and a through hole 63T3 that is shown in FIG. 8B are connected to the conductor layer 633. The through hole 62T5 and two through holes 63T5 shown in FIG. 8B are connected to the conductor layer 635.

FIG. 8C shows a patterned surface of the fourteenth dielectric layer 64. Conductor layers 641a, 641b, 642, 643, 644, 646, 647, and 648 and an inductor conductor layer 645 are formed on the patterned surface of the dielectric layer 64. The conductor layer 646 is connected to the conductor layer 644. In FIG. 8C, the boundary between the conductor layer 644 and the conductor layer 646 is shown as a dotted line. The through hole 63T1a and a through hole 64T1a that is shown in FIG. 8C are connected to the conductor layer 641a. The through hole 63T1b and a through hole 64T1b that is shown in FIG. 8C are connected to the conductor layer 641b. The through holes 63T3 and 63T4 are respectively connected to through holes 64T3 and 64T4 shown in FIG. 8C. The two through holes 63T5 and a through hole 64T5 that is shown in FIG. 8C are connected to the conductor layer 645.

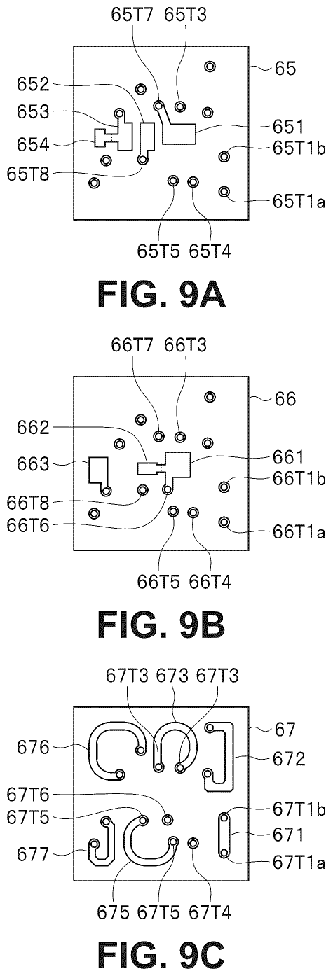

FIG. 9A shows a patterned surface of the fifteenth dielectric layer 65. Conductor layers 651, 652, 653, and 654 are formed on the patterned surface of the dielectric layer 65. The conductor layer 654 is connected to the conductor layer 653. In FIG. 9A, the boundary between the conductor layer 653 and the conductor layer 654 is shown as a dotted line. The through holes 64T1a, 64T1b, 64T3, 64T4, and 64T5 are respectively connected to through holes 65T1a, 65T1b, 65T3, 65T4, and 65T5 shown in FIG. 9A. Through holes 65T7 and 65T8 shown in FIG. 9A are connected to the conductor layers 651 and 652, respectively.

FIG. 9B shows a patterned surface of the sixteenth dielectric layer 66. Conductor layers 661, 662, and 663 are formed on the patterned surface of the dielectric layer 66. The conductor layer 662 is connected to the conductor layer 661. In FIG. 9B, the boundary between the conductor layer 661 and the conductor layer 662 is shown as a dotted line. The through holes 65T1a, 65T1b, 65T3, 65T4, 65T5, 65T7, and 65T8 are respectively connected to through holes 66T1a, 66T1b, 66T3, 66T4, 66T5, 66T7, and 66T8 shown in FIG. 9B. A through hole 66T6 shown in FIG. 9B is connected to the conductor layer 661.

FIG. 9C shows a patterned surface of the seventeenth dielectric layer 67. Inductor conductor layers 671, 672, 673, 675, 676, and 677 are formed on the patterned surface of the dielectric layer 67. The conductor layer 671 includes a first end and a second end located on the opposite sides of each other in a longitudinal direction of the conductor layer 671. The through hole 66T1a and a through hole 67T1a that is shown in FIG. 9C are connected to a portion near the first end of the conductor layer 671. The through hole 66T1b and a through hole 67T1b that is shown in FIG. 9C are connected to a portion near the second end of the conductor layer 671. The through holes 66T3 and 66T7 and two through holes 67T3, shown in FIG. 9C, are connected to the conductor layer 673. The through holes 66T4 and 66T6 are respectively connected to through holes 67T4 and 67T6 shown in FIG. 9C. The through holes 66T5 and 66T8 and two through holes 67T5, shown in FIG. 9C, are connected to the conductor layer 675.

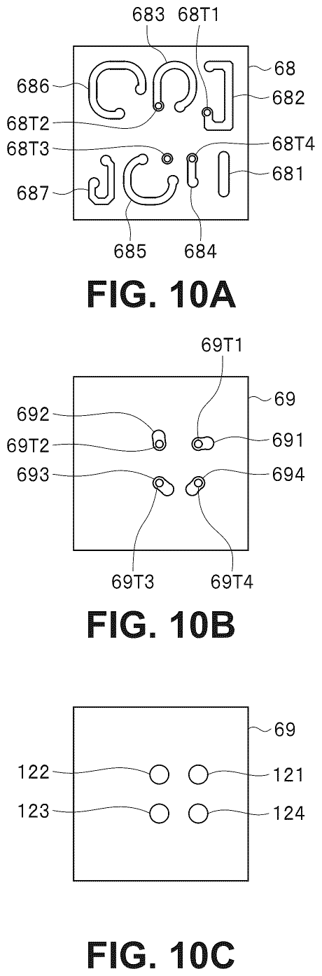

FIG. 10A shows a patterned surface of the eighteenth dielectric layer 68. Inductor conductor layers 681, 682, 683, 684, 685, 686, and 687 are formed on the patterned surface of the dielectric layer 68. The conductor layer 681 includes a first end and a second end located on the opposite sides of each other in a longitudinal direction of the conductor layer 681. The through hole 67T1a is connected to a portion near the first end of the conductor layer 681. The through hole 67T1b is connected to a portion near the second end of the conductor layer 681. A through hole 68T1 shown in FIG. 10A is connected to the conductor layer 682. The two through holes 67T3 and a through hole 68T2 that is shown in FIG. 10A are connected to the conductor layer 683. The through hole 67T4 and a through hole 68T4 that is shown in FIG. 10A are connected to the conductor layer 684. The two through holes 67T5 are connected to the conductor layer 685. The through hole 67T6 is connected to a through hole 68T3 shown in FIG. 10A.

FIG. 10B shows a patterned surface of the nineteenth dielectric layer 69. Conductor layers 691, 692, 693, and 694 are formed on the patterned surface of the dielectric layer 69. The through hole 68T1 and a through hole 69T1 that is shown in FIG. 10B are connected to the conductor layer 691. The through hole 68T2 and a through hole 69T2 that is shown in FIG. 10B are connected to the conductor layer 692. The through hole 68T3 and a through hole 69T3 that is shown in FIG. 10B are connected to the conductor layer 693. The through hole 68T4 and a through hole 69T4 that is shown in FIG. 10B are connected to the conductor layer 694.

FIG. 10C shows a surface opposite to the patterned surface of the nineteenth dielectric layer 69. The surface opposite to the patterned surface of the dielectric layer 69 is hereinafter referred to as an electrode formation surface of the dielectric layer 69. The electrodes 121, 122, 123, and 124 are formed on the electrode formation surface of the dielectric layer 69. The through holes 69T1, 69T2, 69T3, and 69T4 are connected to the electrodes 121, 122, 123, and 124, respectively.

The element portion 50 is formed by stacking the first to nineteenth dielectric layers 51 to 69 together such that the patterned surface of the first dielectric layer 51 serves as the second surface 50B of the element portion 50 and the electrode formation surface of the nineteenth dielectric layer 69 serves as the first surface 50A of the element portion 50.

Each of the plurality of through holes shown in FIG. 5A to FIG. 10B is connected to a conductor layer that the each through hole overlaps with in the stacking direction T or to another through hole that the each through hole overlaps with in the stacking direction T, when the first to nineteenth dielectric layers 51 to 69 are stacked together. Of the plurality of through holes shown in FIG. 5A to FIG. 10B, a through hole located within an electrode or a conductor layer is connected to the electrode or the conductor layer.

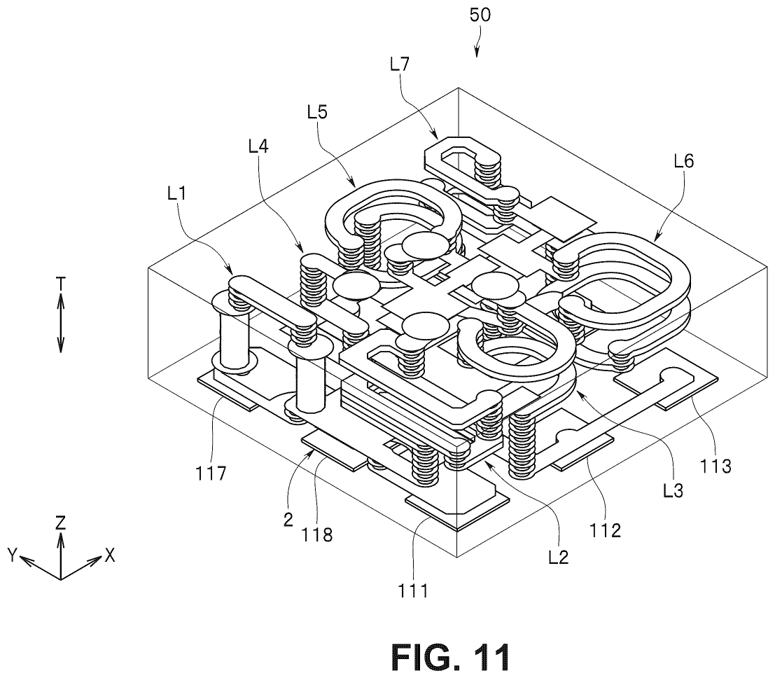

FIG. 11 shows an inside of the element portion 50 formed by stacking the first to nineteenth dielectric layers 51 to 69 together. As shown in FIG. 11, the plurality of conductor layers and the plurality of through holes shown in FIG. 5A to FIG. 10C are stacked together inside the element portion 50.

Correspondences between the components of the filter circuit 1 shown in FIG. 1 and the components inside the element portion 50 shown in FIG. 5A to FIG. 10C will be described below. The inductor L1 includes the inductor conductor layers 671 and 681, the conductor layers 641a and 641b, and the through holes 53T1a, 54T1a, 54T1b, 55T1a, 55T1b, 57T1a, 57T1b, 58T1a, 58T1b, 60T1a, 60T1b, 61T1a, 61T1b, 62T1a, 62T1b, 63T1a, 63T1b, 64T1a, 64T1b, 65T1a, 65T1b, 66T1a, 66T1b, 67T1a, and 67T1b.

The inductor L2 includes the inductor conductor layers 602, 612, 622, 632, 672, and 682, and the plurality of through holes that connect these conductor layers. The conductor layer 682 is connected to the electrode 121 via the through hole 68T1, the conductor layer 691, and the through hole 69T1.

The inductor L3 includes the inductor conductor layers 623, 633, 673, and 683, and the through holes 62T3, 63T3, 64T3, 65T3, 66T3, and 67T3. The conductor layer 683 is connected to the electrode 122 via the through hole 68T2, the conductor layer 692, and the through hole 69T2.

The inductor L4 includes the inductor conductor layers 614 and 684, the conductor layers 533 and 571, and the through holes 52T4, 53T4, 54T4, 55T4, 57T4, 58T4, 60T4, 61T4, 62T4, 63T4, 64T4, 65T4, 66T4, and 67T4.

The inductor L5 includes the inductor conductor layers 635, 645, 675, and 685, and the through holes 63T5, 64T5, 65T5, 66T5, and 67T5.

The inductor L6 includes the inductor conductor layers 606, 616, 626, 636, 676, and 686, and the plurality of through holes that connect these conductor layers. The inductor L7 includes the inductor conductor layers 607, 617, 627, 637, 677, and 687, and the plurality of through holes that connect these conductor layers.

The capacitor C1 includes the conductor layers 521, 522, 531, and 541, and the dielectric layers 52 and 53 between these conductor layers. The capacitor C2 includes the electrodes 111 and 117, the conductor layers 521 and 522, and the dielectric layer 51 between the electrodes 111 and 117 and the conductor layers 521 and 522.

The capacitor C3 includes the conductor layers 633 and 642, and the dielectric layer 63 between these conductor layers. The capacitor C4 includes the conductor layers 643 and 651, and the dielectric layer 64 between these conductor layers.

The capacitor C5 includes the conductor layers 651 and 661, and the dielectric layer 65 between these conductor layers. The capacitor C6 includes the conductor layers 652 and 662, and the dielectric layer 65 between these conductor layers.

The capacitor C7 includes the conductor layers 644 and 652, and the dielectric layer 64 between these conductor layers. The capacitor C8 includes the conductor layers 646 and 653, and the dielectric layer 64 between these conductor layers. The capacitor C9 includes the conductor layers 636 and 647, and the dielectric layer 63 between these conductor layers.

The capacitor C10 include the conductor layers 523 and 532, and the dielectric layer 52 between these conductor layers. The capacitor C11 includes the conductor layers 648, 654, and 663, and the dielectric layers 64 and 65 between these conductor layers.

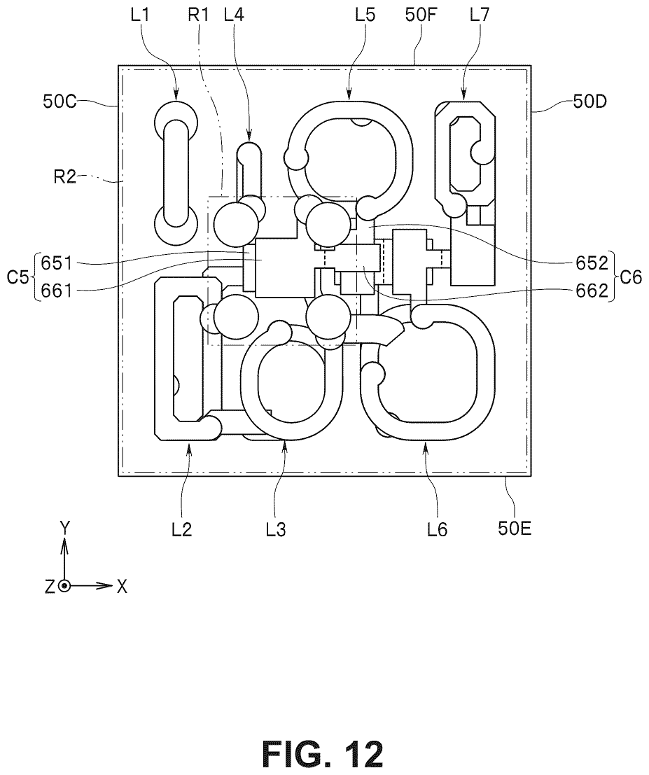

Next, structural features of the filter circuit 1 according to the example embodiment will be described with reference to FIG. 2 to FIG. 12. FIG. 12 is a plan view showing an inside of the element portion 50.

Initially, two regions of the element portion 50 defined by the mounted component 80 will be described. As described above, the mounted component 80 is mounted on the first surface 50A of the element portion 50. The element portion 50 includes a first region R1 which overlaps the mounted component 80 when seen in the stacking direction T, and a second region R2 which does not overlap the mounted component 80 when seen in the stacking direction T. The first region R1 is defined as a three-dimensional region in which an end thereof in the Z direction exists on the first surface 50A, and an end thereof in the −Z direction exists on the second surface 50B. In FIG. 12, an outer edge portion of the first region R1 including an end in the X direction, an end in the −X direction, an end in the Y direction, and an end in the −Y direction of the first region R1 is indicated as a rectangular double-dot line denoted by the reference sign R1.

The second region R2 is defined as a region which is substantially a three-dimensional region surrounded by an outer peripheral surface of the element portion 50, excluding the first region R1. The second region R2 covers at least a part of an outer peripheral portion of the first region R1. In the example embodiment in particular, the second region R2 covers a part of the outer peripheral portion of the first region R1, excluding the end in the Z direction (first surface 50A) and the end in the −Z direction (second surface 50B). In FIG. 12, an outer edge portion of the second region R2 including an end in the X direction, an end in the −X direction, an end in the Y direction, and an end in the −Y direction of the second region R2 is indicated as a rectangular double-dot line denoted by the reference sign R2. Note that in FIG. 12, the outer edge portion of the second region R2 is drawn away from the side surfaces 50C to 50F of the element portion 50, for convenience.

A planar shape of the mounted component 80 (shape when seen in the stacking direction T) may be the same as the shape of the first region R1. Alternatively, the mounted component 80 may include a first part having a planar shape the same as that of the first region R1 and a second part having a planar shape of a size different from that of the planar shape of the first region R1. In this case, the mounted component 80 is mounted on the element portion 50, in an orientation where the first part is located between the element portion 50 and the second part.

Next, features related to the inductors L2, L3, L5, L6, and L7 will be described. The inductor L2 is wound around an axis that extends in a direction parallel to the stacking direction T such that an opening portion surrounded by the inductor L2 is formed. Hereinafter, the opening portion surrounded by the inductor L2 is referred to as an opening portion of the inductor L2. The opening portion of the inductor L2 faces the first surface 50A of the element portion 50. In addition, the entire opening portion of the inductor L2 is located in the second region R2. Hereinafter, an opening portion surrounded by an inductor other than the inductor L2 is referred to as an opening portion of that inductor.

Similarly, each of the inductors L3, L5, L6, and L7 is wound around an axis that extends in a direction parallel to the stacking direction T such that an opening portion surrounded by each of the inductors L3, L5, L6, and L7 is formed. The opening portion of each of the inductors L3, L5, L6, and L7 faces the first surface 50A of the element portion 50. Most of the opening portion of each of the inductors L3 and L5 is located in the second region R2. The entire opening portion of each of the inductors L6 and L7 is located in the second region R2.

The inductor L2 includes the plurality of inductor conductor layers 602, 612, 622, 632, 672, and 682 that are arranged at a predetermined distance in the stacking direction T. Each of the conductors 602, 612, 622, 632, 672, and 682 is wound around an axis that extends in a direction parallel to the stacking direction T to surround the opening portion of the inductor L2.

The inductor L3 includes the plurality of inductor conductor layers 623, 633, 673, and 683 that are arranged at a predetermined distance in the stacking direction T. Each of the conductor layers 623, 633, 673, and 683 is wound around an axis that extends in a direction parallel to the stacking direction T to surround the opening portion of the inductor L3.

The inductor L5 includes the plurality of inductor conductor layers 635, 645, 675, and 685 that are arranged at a predetermined distance in the stacking direction T. Each of the conductor layers 635, 645, 675, and 685 is wound around an axis that extends in a direction parallel to the stacking direction T to surround the opening portion of the inductor L5.

The inductor L6 includes the plurality of inductor conductor layers 606, 616, 626, 636, 676, and 686 that are arranged at a predetermined distance in the stacking direction T. Each of the conductor layers 626, 636, 676, and 686 is wound around an axis that extends in a direction parallel to the stacking direction T to surround the opening portion of the inductor L6. Each of the conductor layers 606 and 616 extends along the opening portion of the inductor L6.

The inductor L7 includes the plurality of inductor conductor layers 607, 617, 627, 637, 677, and 687 that are arranged at a predetermined distance in the stacking direction T. Each of the conductor layers 627, 637, 677, and 687 is wound around an axis that extends in a direction parallel to the stacking direction T to surround the opening portion of the inductor L7. Each of the conductor layers 607 and 617 extends along the opening portion of the inductor L7.

Next, features related to the inductors L1 and L4 will be described. The inductor L1 is wound around an axis that extends in a direction orthogonal to the stacking direction T such that an opening portion surrounded by the inductor L1 is formed. The opening portion of the inductor L1 faces the side surface 50C of the element portion 50.

The inductor L4 has a shape such that an opening portion surrounded by the inductor L4 is not formed.

Next, features related to connection between the inductors L3, L4, and L5, the capacitors C5 and C6, and the resonator 32 will be described with reference to FIG. 1 and FIG. 5 to FIG. 12. As described above, each of the inductors L3, L4, and L5 is configured using the inductor element configured using the plurality of conductors of the element portion 50. On the other hand, the resonator 32 is configured without using the inductor element.

The resonator 32 is provided between the signal port 83 and the signal port 84. The conductor layer 684 constituting the inductor L4 is connected to the electrode corresponding to the signal port 84 via the through hole 68T4, the conductor layer 694, the through hole 69T4, and the electrode 124. The through hole 52T4 constituting the inductor L4 is connected to the electrodes 112, 113, 115, 116, and 119 that are connected to the ground, via the plurality of through holes 51T1 and the conductor layer 525.

The first end 32a of the resonator 32 is electrically connected to the signal port 84. Therefore, the first end 32a of the resonator 32 is electrically connected to the ground via the plurality of through holes 51T1, the conductor layer 525, the inductor L4, the through hole 68T4, the conductor layer 694, the through hole 69T4, and the electrode 124. The inductor L4 electrically connects the first end 32a of the resonator 32 and the ground.

The conductor layer 661 constituting the capacitor C5 is connected to the electrode corresponding to the signal port 83 via the through holes 66T6, 67T6, and 68T3, the conductor layer 693, the through hole 69T3, and the electrode 123. The conductor layer 662 constituting the capacitor C6 is connected to the electrode corresponding to the signal port 83 via the conductor layer 661, the through holes 66T6, 67T6, and 68T3, the conductor layer 693, the through hole 69T3, and the electrode 123.

The second end 32b of the resonator 32 is electrically connected to the signal port 83. Therefore, the second end 32b of the resonator 32 is electrically connected to the capacitor C5 via the through holes 66T6, 67T6, and 68T3, the conductor layer 693, the through hole 69T3, and the electrode 123, and is electrically connected to the capacitor C6 via the conductor layer 661, the through holes 66T6, 67T6, and 68T3, the conductor layer 693, the through hole 69T3, and the electrode 123.

A part where the through hole 61T3 contacts the inductor conductor layer 623 constituting the inductor L3 corresponds to the first end L3a of the inductor L3. The first end L3a of the inductor L3 is electrically connected to the electrodes 112, 113, 115, 116, and 119 that are connected to the ground, via the plurality of through holes 51T1, the conductor layer 525, and the through holes 52T3, 53T3, 54T3, 55T3, 57T3, 58T3, 60T3, and 61T3.

A part where the through hole 66T7 contacts the inductor conductor layer 673 constituting the inductor L3 corresponds to the second end L3b of the inductor L3. The second end L3b of the inductor L3 is electrically connected to the conductor layer 651 constituting the capacitor C5, via the through holes 65T7 and 66T7. The capacitor C5 is electrically connected to the second end L3b of the inductor L3 and the second end 32b of the resonator 32.

A part where the through hole 62T5 contacts the inductor conductor layer 635 constituting the inductor L5 corresponds to the first end La of the inductor L5. The first end L5a of the inductor L5 is electrically connected the electrodes 112, 113, 115, 116, and 119 that are connected to the ground, via the plurality of through holes 51T1, the conductor layer 525, and the through holes 52T5, 53T5, 54T5, 55T5, 57T5, 58T5, 60T5, 61T5, and 62T5.

A part where the through hole 66T8 contacts the inductor conductor layer 675 constituting the inductor L5 corresponds to the second end L5b of the inductor L5. The second end L5b of the inductor L5 is electrically connected to the conductor layer 652 constituting the capacitor C6 via the through holes 65T8 and 66T8. The capacitor C6 is electrically connected to the second end L5b of the inductor L5 and the second end 32b of the resonator 32.

Next, features related to a layout of the inductors L3 and L5, the capacitors C5 and C6, and the resonator 32 will be described with reference to FIG. 2 to FIG. 4 and FIG. 12. The mounted component 80 includes the resonator 32. Therefore, when the main body 10 is seen in the Z direction, the resonator 32 overlaps the first region R1. As shown in FIG. 12, the inductor L3 and the inductor L5 are arranged with most of the first region R1 interposed therebetween when the main body 10 is seen in the Z direction. From these, the inductor L3 and the inductor L5 are arranged with at least a part of the resonator 32 interposed therebetween when the main body 10 is seen in the Z direction.

Furthermore, as shown in FIG. 12, the entire capacitor C5 is located in the first region R1. A part of the capacitor C6 is located in the first region R1. The inductor L3 and the inductor L5 are arranged with the capacitors C5 and C6 interposed therebetween when the main body 10 is seen in the Z direction.

Next, the operation and effects of the filter circuit 1 according to the example embodiment will be described. The filter circuit 1 according to the example embodiment includes the inductors L3 and L5 configured using the inductor element, and the resonator 32 configured without using the inductor element. The first end L3a of the inductor L3, the first end LSa of the inductor L5, and the first end 32a of the resonator 32 are electrically connected to the ground. The capacitor C5 is electrically connected to the second end L3b of the inductor L3 and the second end 32b of the resonator 32. The capacitor C6 is electrically connected to the second end L5b of the inductor L5 and the second end 32b of the resonator 32. According to the example embodiment, such a configuration allows to widen the passband of the filter circuit 1. Hereinafter, this effect will be described with reference to results of simulations. Note that, in the following description, a passband of the filter circuit 1 is assumed to be between 5.15 and 7.125 GHz. Hereinafter, this passband is referred to as an assumed passband.

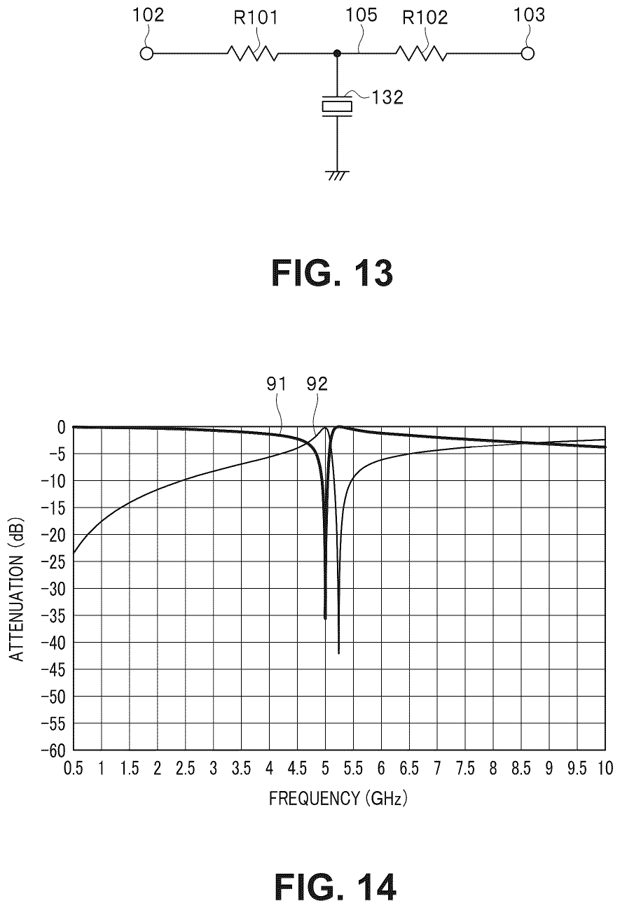

First, a first circuit including a resonator 132 corresponding to the resonator 32 will be described. FIG. 13 is a circuit diagram showing the first circuit. The first circuit includes an input port 102, an output port 103, a signal path 105 connecting the input port 102 and the output port 103, the resonator 132 provided between the signal path 105 and the ground, and resistors R101 and R102 provided on the signal path 105. One end of the resonator 132 is electrically connected to the ground. Another end of the resonator 132 is connected to a connection point of the resistors R101 and R102, and is electrically connected to the input port 102 and the output port 103. Note that in the simulation, a resistance of each of the resistors R101 and R102 is 0Ω.

FIG. 14 is a characteristic diagram showing characteristics of the first circuit obtained by the simulation. In FIG. 14, the horizontal axis indicates frequency and the vertical axis indicates attenuation. In FIG. 14, a curve denoted by the reference sign 91 indicates pass attenuation characteristics between the input port 102 and the output port 103, and a curve denoted by the reference sign 92 indicates return attenuation characteristics at the input port 102. Note that the return attenuation characteristics at the output port 103 substantially coincides with the return attenuation characteristics at the input port 102. In the first circuit, the attenuation of the return attenuation characteristics (hereinafter, referred to as return attenuation) at 5.15 GHz is-9.221 dB, and the return attenuation at 5.9 GHz is-6.518 dB.

As shown in FIG. 14, in the return attenuation characteristics of the first circuit, it can be seen that an attenuation pole is formed in the assumed passband, and an absolute value of the return attenuation decreases rapidly as the frequency increases from the attenuation pole.

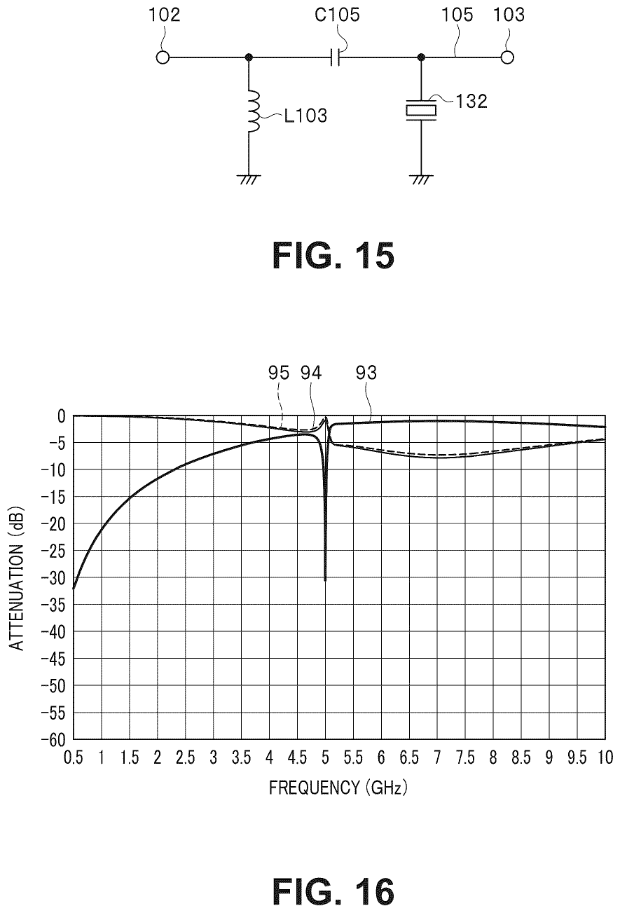

Next, a second circuit including an inductor L103, a capacitor C105, and the resonator 132 corresponding to the inductor L3, the capacitor C5, and the resonator 32, respectively, will be described. FIG. 15 is a circuit diagram showing the second circuit. The second circuit includes the inductor L103 and the capacitor C105 instead of the resistors R101 and R102 in the first circuit. The inductor L103 is provided between the signal path 105 and the ground. One end of the inductor L103 is electrically connected to the ground.

The capacitor C105 is provided on the signal path 105, and is electrically connected to another end of the inductor L103 and the other end of the resonator 132. Note that in the second circuit, the other end of the inductor L103 is electrically connected to the input port 102, and the other end of the resonator 132 is electrically connected to the output port 103.

In the simulation, an inductance of the inductor L103 is 1 nH, and a capacitance of the capacitor C105 is 1.3 pF.

FIG. 16 is a characteristic diagram showing characteristics of the second circuit obtained by the simulation. In FIG. 16, the horizontal axis indicates frequency and the vertical axis indicates attenuation. In FIG. 16, a curve denoted by the reference sign 93 indicates pass attenuation characteristics between the input port 102 and the output port 103, a curve denoted by the reference sign 94 indicates return attenuation characteristics at the input port 102, and a curve denoted by the reference sign 95 indicates return attenuation characteristics at the output port 103. In the second circuit, the return attenuation at 5.15 GHz is-5.233 dB, and the return attenuation at 5.9 GHz is-6.234 dB.

As shown in FIG. 16, in the second circuit, an absolute value of the return attenuation increases as the frequency increases in the assumed passband. From the result, it can be seen that a band-pass filter including the second circuit can widen the passband to a higher frequency side than a band-pass filter including the first circuit. That is, according to the example embodiment, the wide passband can be achieved by employing a relatively simple configuration in which the inductor L3 and the capacitor C5 are provided.

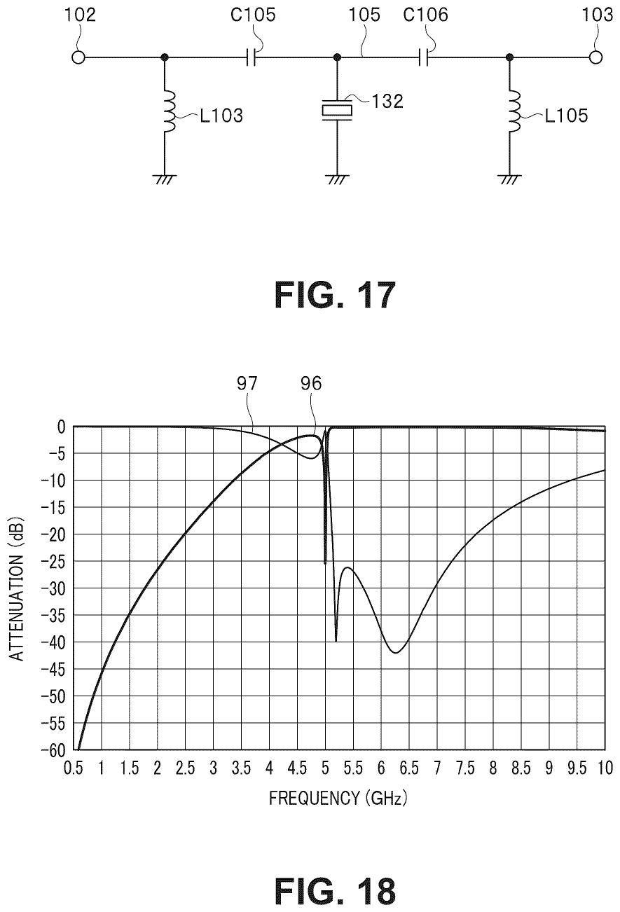

Next, a third circuit including inductors L103 and L105, capacitors C105 and C106, and the resonator 132 corresponding to the inductors L3 and L5, the capacitors C5 and C6, and the resonator 32, respectively, will be described. FIG. 17 is a circuit diagram showing the third circuit. The third circuit includes the inductor L105 and the capacitor C106 in addition to the components of the second circuit. The inductor L105 is provided between the signal path 105 and the ground. One end of the inductor L105 is electrically connected to the ground.

The capacitor C106 is provided on the signal path 105, and is electrically connected to another end of the inductor L105 and the other end of the resonator 132. Note that in the third circuit, the other end of the inductor L103 is electrically connected to the input port 102, and the other end of the inductor L105 is electrically connected to the output port 103.

In the simulation, an inductance of each of the inductors L103 and L105 is 1 nH, and a capacitance of each of the capacitors C105 and C106 is 1.3 pF.

FIG. 18 is a characteristic diagram showing characteristics of the third circuit obtained by the simulation. In FIG. 18, the horizontal axis indicates frequency and the vertical axis indicates attenuation. In FIG. 18, a curve denoted by the reference sign 96 indicates pass attenuation characteristics between the input port 102 and the output port 103, and a curve denoted by the reference sign 97 indicates return attenuation characteristics at the input port 102. Note that return attenuation characteristics at the output port 103 substantially coincides with the return attenuation characteristics at the input port 102. In the third circuit, the return attenuation at 5.15 GHz is-26.88 dB, and the return attenuation at 5.9 GHz is-35.31 dB.

As shown in FIG. 18, in the third circuit, an absolute value of the return attenuation is greater in a wide frequency band including the assumed passband compared to the second circuit. From the result, it can be seen that a band-pass filter including the third circuit can widen the passband to a higher frequency side compared to the band-pass filter including the second circuit. That is, according to the example embodiment, the wider passband can be achieved by employing a relatively simple configuration in which the inductor L5 and the capacitor C6 are provided in addition to the inductor L3 and the capacitor C5.

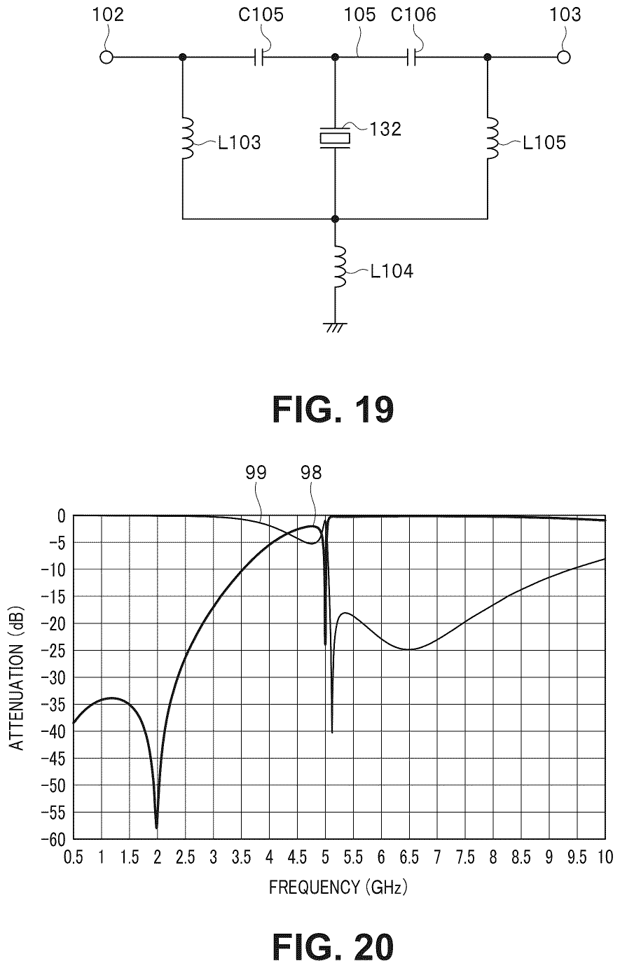

Next, a fourth circuit in which the inductors L103 and L105 in the third circuit are inductively coupled with each other will be described. FIG. 19 is a circuit diagram showing the fourth circuit. The fourth circuit includes an inductor L104 in addition to the components of the third circuit. The inductor L104 electrically connects one end of each of the inductors L103 and L105, as well as the resonator 132, to the ground.

In the simulation, an inductance of each of the inductors L103, L104, and L105 is 1 nH, and a capacitance of each of the capacitors C105 and C106 is 1.3 pF.

FIG. 20 is a characteristic diagram showing characteristics of the fourth circuit obtained by the simulation. In FIG. 20, the horizontal axis indicates frequency and the vertical axis indicates attenuation. In FIG. 20, a curve denoted by the reference sign 98 indicates pass attenuation characteristics between the input port 102 and the output port 103, and a curve denoted by the reference sign 99 indicates return attenuation characteristics at the input port 102. Note that return attenuation characteristics at the output port 103 substantially coincides with the return attenuation characteristics at the input port 102.

As shown in FIG. 20, in the pass attenuation characteristics of the fourth circuit, an attenuation pole is formed in a frequency domain lower than the assumed passband. As seen from the result, according to the example embodiment, an absolute value of attenuation of the pass attenuation characteristics in the frequency domain on a lower frequency side than the passband can be increased by inductively coupling the inductors L3 and L5. Note that the inductive coupling of the inductors L3 and L5 can be achieved by the conductor layer 525 and the plurality of through holes 51T1, for example.

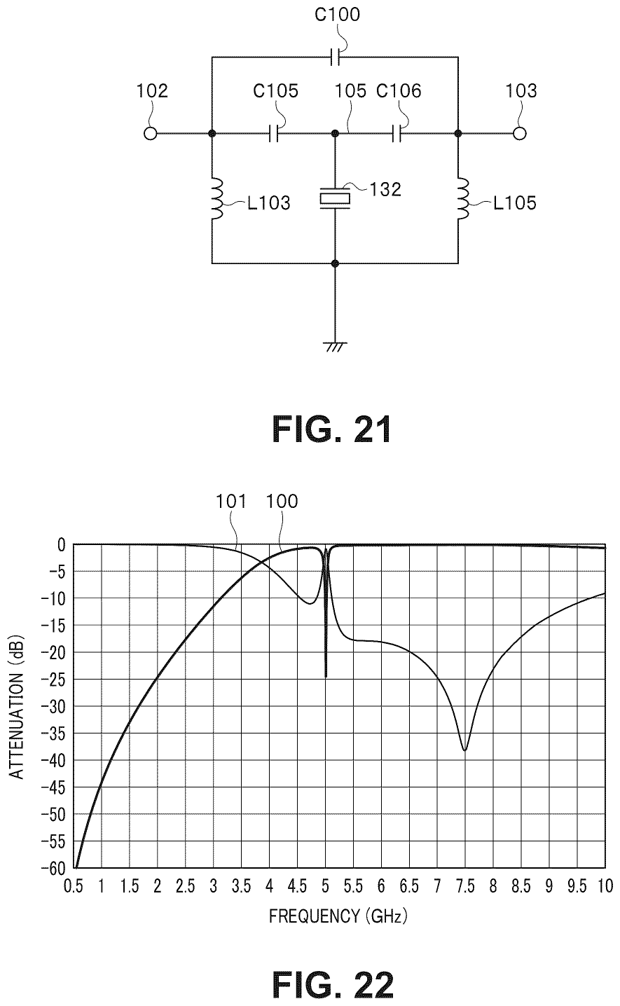

Next, a fifth circuit in which the inductors L103 and L105 in the third circuit are capacitively coupled with each other will be described. FIG. 21 is a circuit diagram showing the fifth circuit. The fifth circuit includes a capacitor C100 in addition to the components of the third circuit. The capacitor C100 is electrically connected to the other end of each of the inductors L103 and L105.

In the simulation, an inductance of each of the inductors L103 and L105 is 1 nH, a capacitance of each of the capacitor C105 and C106 is 1.3 pF, and a capacitance of the capacitor C100 is 0.1 pF.

FIG. 22 is a characteristic diagram showing characteristics of the fifth circuit obtained by the simulation. In FIG. 22, the horizontal axis indicates frequency and the vertical axis indicates attenuation. In FIG. 22, a curve denoted by the reference sign 100 indicates pass attenuation characteristics between the input port 102 and the output port 103, and a curve denoted by the reference sign 101 indicates return attenuation characteristics at the input port 102. Note that return attenuation characteristics at the output port 103 substantially coincides with the return attenuation characteristics at the input port 102.

As shown in FIG. 22, in the return attenuation characteristics of the fifth circuit, an absolute value of the return attenuation in a frequency domain lower than the assumed passband is small. Therefore, in the band-pass filter including the fifth circuit, the characteristics in the frequency domain lower than the passband deteriorate by capacitively coupling the inductors L103 and L105. In the example embodiment, in order to suppress that the inductors L3 and L5 capacitively couple with each other, the inductors L3 and L5 are arranged at a distance. According to the example embodiment, this makes it possible to suppress the deterioration of the characteristics in the frequency domain lower than the passband.

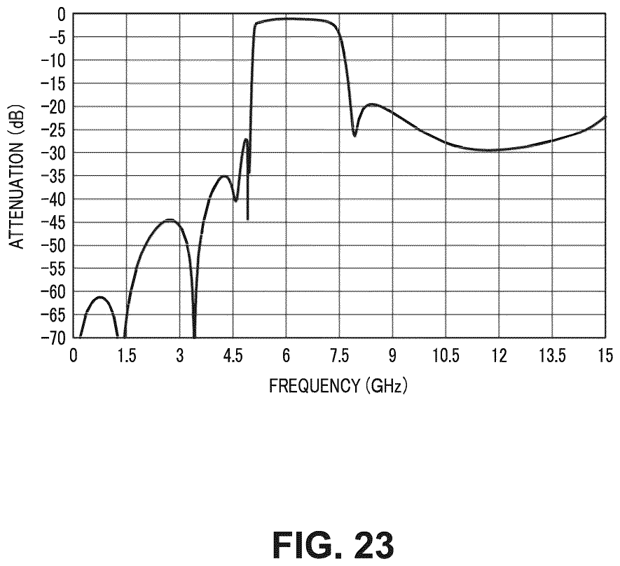

Next, an example of characteristics of the filter circuit 1 according to the example embodiment will be shown. FIG. 23 is a characteristic diagram showing pass attenuation characteristics of the filter circuit 1. In FIG. 23, the horizontal axis indicates frequency and the vertical axis indicates attenuation. From FIG. 23, it can be seen that the filter circuit 1 has practically sufficient characteristics as a band-pass filter.

Next, other effects of the filter circuit 1 according to the example embodiment will be described. In the example embodiment, most of the opening portion of each of the inductors L3 and L5 is located in the second region R2. Therefore, according to the example embodiment, it is possible to achieve the desired characteristics by suppressing mutual interactions of electromagnetic fields between each of the inductors L3 and L5 and the mounted component 80.

Similarly, in the example embodiment, the entire opening portion of each of the inductors L2, L6, and L7 is located in the second region R2. Therefore, according to the example embodiment, it is possible to achieve the desired characteristics by suppressing mutual interactions of electromagnetic fields between each of the inductors L2, L6, and L7 and the mounted component 80.

Note that the disclosure is not limited to the example embodiment described above, and various modifications are possible. For example, the filter circuit of the disclosure is not limited to the band-pass filter, and can be applied to other filters such as a low-pass filter and a high-pass filter. Also, the filter circuit of the disclosure can be applied to an electronic component including a plurality of resonators, such as a branching filter that separates a plurality of signals with a different frequency bands.

As described above, a filter circuit according to one embodiment of the disclosure includes an input port, an output port, a signal path connecting the input port and the output port, a first inductor provided between the signal path and a ground and including a first end electrically connected to the ground and a second end opposite to the first end, a resonator provided between the signal path and the ground and including a third end electrically connected the ground and a fourth end opposite to the third end, and a first capacitor provided on the signal path and electrically connected to the second end of the first inductor and the fourth end of the resonator. The first inductor is configured using an inductor element. The resonator is configured without using the inductor element.

The filter circuit according to one embodiment of the disclosure may further include a third inductor electrically connecting the third end of the resonator and the ground.

The filter circuit according to one embodiment of the disclosure may further include a second inductor provided between the signal path and the ground and including a fifth end electrically connected to the ground and a sixth end opposite to the fifth end, and a second capacitor provided on the signal path and electrically connected to the sixth end of the second inductor and the fourth end of the resonator. The second inductor may be configured using the inductor element.

If the filter circuit according to one embodiment of the disclosure includes the second inductor and the second capacitor, the filter circuit according to one embodiment of the disclosure may further include a main body for integrating the input port, the output port, the first inductor, the second inductor, the resonator, the first capacitor, and the second capacitor. The first inductor and the second inductor may be arranged with the first capacitor and the second capacitor interposed therebetween when the main body is seen in one predetermined direction. Also, the first inductor and the second inductor may be arranged with at least a part of the resonator interposed therebetween when the main body is seen in one predetermined direction. The main body may include an element portion including the first inductor, the second inductor, the first capacitor, and the second capacitor, and a mounted component including the resonator and mounted on the element portion.

In the filter circuit according to one embodiment of the disclosure, the resonator may be configured using an acoustic wave element.

In the filter circuit of the disclosure, the first inductor is configured using the inductor element, and the resonator is configured without using the inductor element. One end of each of the first inductor and the resonator is electrically connected to the ground. The first capacitor is electrically connected to the second end of the first inductor and the fourth end of the resonator. With this, according to the disclosure, the filter circuit capable of achieving a wide passband with a simple structure can be provided.

Obviously, various forms and modifications of the disclosure can be practiced in the light of the above teachings. Thus, it is to be understood that, within the scope of the appended claims and equivalents thereof, the disclosure may be practiced in forms other than the foregoing example embodiment.

1. A filter circuit comprising:
an input port;
an output port;
a signal path connecting the input port and the output port;
a first inductor provided between the signal path and a ground, and including a first end electrically connected to the ground and a second end opposite to the first end;
a resonator provided between the signal path and the ground, and including a third end electrically connected to the ground and a fourth end opposite to the third end; and
a first capacitor provided on the signal path, and electrically connected to the second end of the first inductor and the fourth end of the resonator, wherein:
the first inductor is configured using an inductor element; and
the resonator is configured without using the inductor element.

2. The filter circuit according to claim 1, further comprising a third inductor electrically connecting the third end of the resonator and the ground.

3. The filter circuit according to claim 1, further comprising:
a second inductor provided between the signal path and the ground, and including a fifth end electrically connected to the ground and a sixth end opposite to the fifth end; and
a second capacitor provided on the signal path, and electrically connected to the sixth end of the second inductor and the fourth end of the resonator, wherein
the second inductor is configured using the inductor element.

4. The filter circuit according to claim 3, further comprising:
a main body for integrating the input port, the output port, the first inductor, the second inductor, the resonator, the first capacitor, and the second capacitor, wherein
the first inductor and the second inductor are arranged with the first capacitor and the second capacitor interposed therebetween when the main body is seen in one predetermined direction.

5. The filter circuit according to claim 3, further comprising:
a main body for integrating the input port, the output port, the first inductor, the second inductor, the resonator, the first capacitor, and the second capacitor, wherein
the first inductor and the second inductor are arranged with at least a part of the resonator interposed therebetween when the main body is seen in one predetermined direction.

6. The filter circuit according to claim 5, wherein the main body includes an element portion including the first inductor, the second inductor, the first capacitor, and the second capacitor, and a mounted component that includes the resonator and is mounted on the element portion.

7. The filter circuit according to claim 1, wherein the resonator is configured using an acoustic wave element.
